(19) United States
(12) Patent Application Publication
(10) Pub. No.: US 2011/0254019 A1
(43) Pub. Date: Oct. 20, 2011

(54) ADAPTED SEMICONDUCTOR LIGHT EMITTING DEVICE AND METHOD FOR MANUFACTURING THE SAME

(76) Inventor: Chen Hsu, Taoyuan County (TW)

(21) Appl. No.: 13/121,021

(22) PCT Filed: Sep. 26, 2008
(86) PCT No.: PCT/CN2008/072551

§ 371 Date: Mar. 25, 2011

(51) Int. Cl. H01L 33/58

(52) U.S. Cl. 257/77; 257/98; 257/43; 257/76; 438/3; 438/29; 257/E33.06

(57) ABSTRACT

A semiconductor light-emitting device with light-modulating function and a method of fabrication the same are provided. The semiconductor light-emitting device as provided includes a light-emitting layer and a super-paramagnetic layer. The light-emitting layer functions for emitting a first light. In particular, a portion or most of the first light is modulated by the super-paramagnetic layer into a second light when the first light passes through the super-paramagnetic layer. In some embodiments, the semiconductor light-emitting device is designed in such a way that a portion of the first light, which is not modulated into the second light, blends with the second light into a third light, e.g., a white light.

### FIELD OF THE INVENTION

The invention herein relates to a semiconductor light-emitting device, and more particularly, to a semiconductor light-emitting device with light-modulating function.

### BACKGROUND OF THE INVENTION

The semiconductor light-emitting device, e.g. the light-emitting diode (LED), is a quite important solid state device capable of converting the electrical energy into the light. A typical semiconductor light-emitting device generally includes one or more light-emitting layers formed by semiconductor materials, which are sandwiched between the doped layers of opposite doping types. Holes and electrons are injected into the light-emitting layers when a bias voltage is applied across the doped layer, and then the holes and electrons are combined to produce the light. The light is emitted from the light-emitting layers in all directions, and is emitted from all surfaces of the semiconductor light-emitting device, wherein the light emitted towards the top surface of the semiconductor light-emitting device is useful.

One disadvantage of the conventional LED is that the white light cannot be generated from the light-emitting layers thereof. One solution for the conventional LED to generate the white light is to mix or blend different color lights generated by the different LEDs into the white light. For example, the lights which are emitted respectively from the red, green and blue LEDs or the lights which are emitted respectively from the blue and yellow LEDs could be mixed to generate the white light. One disadvantage of such solution, however, is that it needs many LEDs to generate a single color light, such that the cost thereof may be increased significantly. Besides, because the different color lights are usually generated by the different types of LEDs, it must need a complicated process to combine these LEDs into one device. Such device must need different control voltages and thus a complicated control circuit because of the different types of diodes. Furthermore, the characteristics such as long wavelength and stability of these devices may also get degradation due to the different aging behaviors of the different types of LEDs.

Recently, it is applicable to use the blue LED single chip, surrounded by yellow light phosphors, polymers or dyes, to convert the light emitted therefrom into the white light. The details of such method are disclosed in U.S. Pat. Nos. 5,813,753, 5,959,316 and 6,069,440. The frequency of parts of the light emitted from the LED is down-converted by the surrounding materials (to emit the light of a lower frequency), such that the color of the light is changed. For example, by surrounding the nitride-based blue LED which the yellow phosphors, a part of the blue light emitted from the nitride-based blue LED will pass through the phosphors without change, while the remaining part of light will be down-converted into the yellow light. In such a case, the lights emitted from the LED, including the yellow light and the blue light, will blend into white light.

However, the addition of phosphors makes the LED more complicated, which needs a more complex package procedure. Besides, the net emitting efficiency will be reduced due to the absorption of the phosphors and the Stoke's shift from the blue to yellow. The phosphors are also disadvantageous in the decay of reliability. Furthermore, the blue Halo effect occurs in such LEDs.

Some researchers devote to produce the LED components on a ZnSe substrate. The ZnSe substrate is doped with dopants of n-type, such as I [symbol] Al [symbol] Cl [symbol] Br [symbol] Ga or In, so as to create fluorescent centers therein. Similar to the addition of phosphors during the package procedures, these fluorescent centers are used for adsorbing a part of the light emitted from the LED components and then emitting the light with longer wavelengths. The details of such method can be found in U.S. Pat. No. 6,337,536 and Japan Pat. App. No. 2004-072047.

On the other hand, some researchers put forth effort to produce multiple quantum well in the pn-junction of the LED for emitting lights with different wavelengths. The details of such technology are disclosed in U.S. Pat. Nos. 5,851,905, 6,303,404, 6,504,171 and 6,734,467. However, it is hard to achieve the long-wavelength band with good luminous efficiency by using the quantum well as the light-emitting layer structure of the LED in general. For example, the emission spectrum of LED having the quantum well structure as the light-emitting layer has a certain relationship with the luminous efficiency under the wavelength larger than 550 nm. With the increasing of the range of spectrum, the luminous efficiency of the light-emitting layer having the quantum well will decrease sharply. That is, the use of quantum well structure achieves an increased luminous efficiency merely in the narrow-spectrum.

Recently, the adapted LED constructed by a short wavelength LED (UV LED) and a re-emitting semiconductor structure is revealed. The re-emitting semiconductor structure comprises three potential wells not located within the pn-junction. The three potential wells are respectively used for emitting blue, green and violet lights after absorbing the UV light. The details of such a technology are disclosed in U.S. Pat. No. 7,402,831.

From the above descriptions about the white light emission or near-white light emission of LED of the relevant prior arts, it is clear that current techniques of LED have the problems of manufacturing complexity and low conversion efficiency. Therefore, it is an aspect of the present application to provide a simple single-chip white light semiconductor light-emitting device without the need of phosphors or re-emitting semiconductor structure, so as to eliminate the drawbacks of low luminous efficiency and complex fabrication process arising from converting the original emitting light into a secondary light.

In addition, for the semiconductor light-emitting device, it needs to adopt several types of LEDs, e.g. the blue, green and red LEDs, for use in display, e.g. LED display pane to achieve the multi-color display. Apparently, it still needs to improve the technique of LED field. Thus, it is a further aspect of this invention to provide a single-chip semiconductor light-emitting device with light-modulating function for the application of LED display.

### SUMMARY OF INVENTION

In a preferred embodiment of the present invention, the semiconductor light-emitting device includes a substrate, a multi-layer structure and a super-paramagnetic layer. The substrate has an upper surface and a lower surface. The multi-layer structure is formed on the upper surface of the substrate and includes a light-emitting layer. The light-emitting layer is used for emitting a first light. The multi-layer structure has a top surface. The super-paramagnetic layer is formed over the top surface of the multi-layer structure and/or formed over the lower surface of the substrate. The first light is modulated by the super-paramagnetic layer into a second light upon passing through the super-paramagnetic layer.

In another preferred embodiment of the present invention, a method of fabricating a semiconductor light-emitting device is provided. First, a substrate is provided, wherein the substrate has an upper surface and a lower surface. According to the present method, a multi-layer structure is subsequently formed on the upper surface of the substrate. The multi-layer structure includes a light-emitting layer for emitting a first light and has a top surface. At last, a super-paramagnetic layer is formed over the top surface of the multi-layer structure and/or formed over the lower surface of the substrate. According to the present invention, a portion or most of the first light is modulated by the super-paramagnetic layer into a second light when the first light passes through the super-paramagnetic layer.

The super-paramagnetic layer is formed by a paramagnetic material. Examples of such material includes MnZn ferrite, NiZn ferrite, NiZnCu, Ni—Fe—Mo alloy, Fe-based amorphous material, FeNi-based amorphous material, Co-based amorphous material, nano-crystalline alloy, ferrite core material, superconducting material, ZnO, Al₂O₃, GaN, GaInN, GaInP, SiO₂, Si₃N₄, AlN, BN, Zr₂O₃, Au, Ag, Cu or Fe, and the like. Besides, the super-paramagnetic layer has a pattern formed by a plurality of nano-scale holes or a plurality of nano-scale protrusions.

The above objects and advantages of the present invention will become more readily apparent to those ordinarily skilled in the art after reviewing the following detailed descriptions and accompanying drawings.

### BRIEF DESCRIPTION OF THE DRAWINGS

FIG. 1 is a schematic cross-sectional view of a semiconductor light-emitting device in accordance with one preferred embodiment of the present invention.

FIG. 2A is an SEM (scanning electron microscope) photo showing the surface structure view of a AAO layer under a scanning electron microscope of one embodiment of the present invention.

FIG. 2B is an SEM photo showing the MnZnFeO ferrite layer precipitated on the nanoporous anodic alumina oxide (AAO) layer.

FIG. 2C is a drawing showing the magnetic measurement results of the MnZnFeO ferrite layer with a superconducting quantum interference device (SQUID).

FIG. 2D is a fluorescent spectrum of an excited AAO/GaN/Sapphire multi-layer structure and two respective excited MnZnFe ferrite/AAO/GaN/Sapphire multi-layer structure.

FIG. 3 is a schematic cross-sectional view of a semiconductor light-emitting device in accordance with another preferred embodiment of the present invention.

FIG. 4 is a schematic cross-sectional view of a semiconductor light-emitting device in accordance with a further preferred embodiment of the present invention.

FIG. 5 is a schematic cross-sectional view of a semiconductor light-emitting device in accordance with still another preferred embodiment of the present invention.

FIG. 6 is a schematic cross-sectional view of a semiconductor light-emitting device in accordance with still another preferred embodiment of the present invention.

FIG. 7 is a schematic cross-sectional view of a semiconductor light-emitting device in accordance with still another preferred embodiment of the present invention.

FIG. 8A to FIG. 8D are schematic cross-sectional views for illustrating the respective steps of the process for manufacturing a semiconductor light-emitting device in accordance with one preferred embodiment of the present invention.

### DETAILED DESCRIPTION OF THE INVENTION

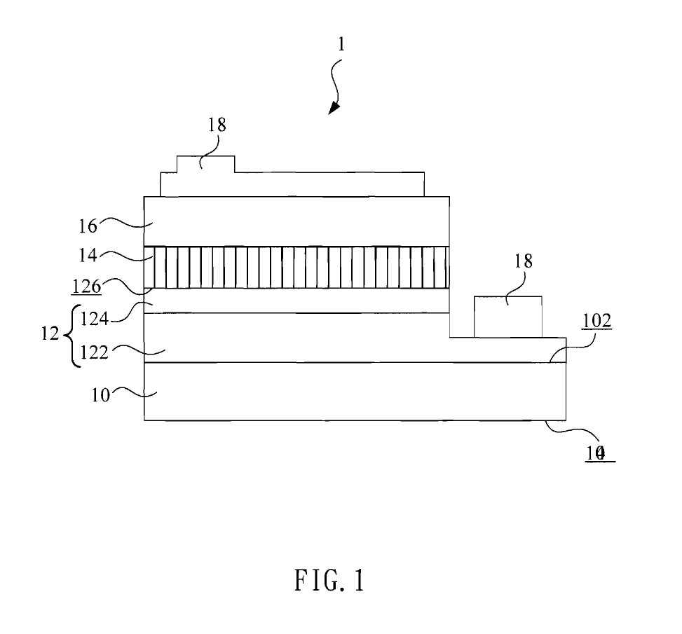

Please refer to FIG. 1, which is a schematic cross-sectional view of a semiconductor light-emitting device 1 in accordance with one preferred embodiment of the present invention. In particular, the semiconductor light-emitting device 1 has light-modulating function.

As shown in FIG. 1, the semiconductor light-emitting device 1 includes a substrate 10, a multi-layer structure 12, a super-paramagnetic layer 14, a first semiconductor cladding layer 16 and at least one electrode 18.

In practical applications, the substrate 10 may be made of SiO₂, Si, Ge, GaN, GaAs, GaP, AlN, sapphire, spinnel, Al₂O₃, SiC, ZnO, MgO, LiAlO2, LiGaO₂ or MgAl₂O₄, and the like.

Also as shown in FIG. 1, the substrate 10 has an upper surface 102 and a lower surface 104 opposite to the upper surface 102. The multi-layer structure 12 is formed on the upper surface 102 of the substrate 10. Similar to a typical semiconductor light-emitting device, the multi-layer structure 12 includes a light-emitting layer 124. The light-emitting layer 124 functions for emitting a first light, e.g. a blue light or UV light. The multi-layer structure 12 also includes a second semiconductor cladding layer 122 which is formed prior to the formation of the light-emitting layer 124, as shown in FIG. 1. Alternatively, a buffer layer (not shown in FIG. 1) may be formed over the upper surface 102 of the substrate 10 prior to the formation of the second semiconductor cladding layer 122.

In one embodiment, the light-emitting layer 124 may be a pn-junction, a double hetero-junction or a multiple quantum well.

In one embodiment, the light-emitting layer 124 is formed by a III-V compound or a II-VI compound, such as GaN, InGaN, AlGaN or AlGaInN, and the like, which has been widely used.

Referring back to FIG. 1, the multi-layer structure 12 has a top surface 126. The super-paramagnetic layer 14 is formed over the top surface 126 of the multi-layer structure 12. In particular, when the first light passes through the super-paramagnetic layer 14, a portion or most of the first light is modulated by the super-paramagnetic layer 14 into a second light. For example, the blue light may be modulated into the yellow light, i.e. the light complementary to the blue light, or the UV light may be modulated into the blue light due to the magneto-optical effect caused by the super-paramagnetic layer 14 to the first light.

It should be noted that, instead of the conventional method that adopts the phosphors or a re-emitting semiconductor structure for absorbing the originally-emitted light first and then emitting a light with a relatively lower frequency, the semiconductor light-emitting device in accordance with the invention utilizes the magneto-optical effect caused by the super-paramagnetic layer to the originally-emitted light to directly modulate the frequency of the originally-emitted light. Apparently, the luminous efficiency the semiconductor light-emitting device of the invention, which converts the originally-emitted light into a secondary light, is higher than that of the conventional methods.

In practical applications, the super-paramagnetic layer 14 is formed by a paramagnetic material, such as MnZn ferrite (e.g. MnZnFeO ferrite (MnZnFe ferrite)), NiZn ferrite, NiZnCu, Ni—Fe—Mo alloy, Fe-based amorphous material, Fe—Ni-based amorphous material, Co-based amorphous material, nanocrystalline alloy, ferrite core material, superconducting material, ZnO, Al₂O₃, GaN, GaInN, GaInP, SiO₂, Si₃N₄, AlN, BN, Zr₂O₃, Au, Ag, Cu or Fe, and the like. Besides, the super-paramagnetic layer 14 has a pattern formed by a plurality of nano-scale holes or a plurality of nano-scale protrusions. The specific range of aperture of these holes or outer diameter of these protrusions is in response to the light of a specific frequency. Take the current LED application as an example (the frequency is ranged from UV light to red light), the aperture of these holes or the outer diameter of these protrusions is properly ranged from tens of nanometers to hundreds of nanometers. In the fabrication process, the frequency of the light to be modulated will be changed by fine tuning the aperture of the holes or the outer diameter of the protrusions. Thus, in the present invention, the aperture of the holes (or the outer diameter of the protrusions) of the super-paramagnetic layer is designed depending on the frequency of the originally-emitted light and the frequency of the modulated light to be obtained.

In addition, the super-magnetic characteristic exists merely when the super-paramagnetic layer 14 has a specific range of thickness, and the thickness of the super-magnetic layer, required to maintain the super-paramagnetic characteristic depends on the paramagnetic material formed on the layer. A typical range of the thickness is several nanometers to hundreds of nanometers. Preferably, the thickness of the super-paramagnetic layer 14 should not affect the overall transmittance of the semiconductor light-emitting device 1.

As to the fabrication method of the mentioned super-paramagnetic layer, it is achievable by various conventional deposition processes, for example, PVD, CVD or MOCVD, with the lithography process and the dry etching or wet etching process.

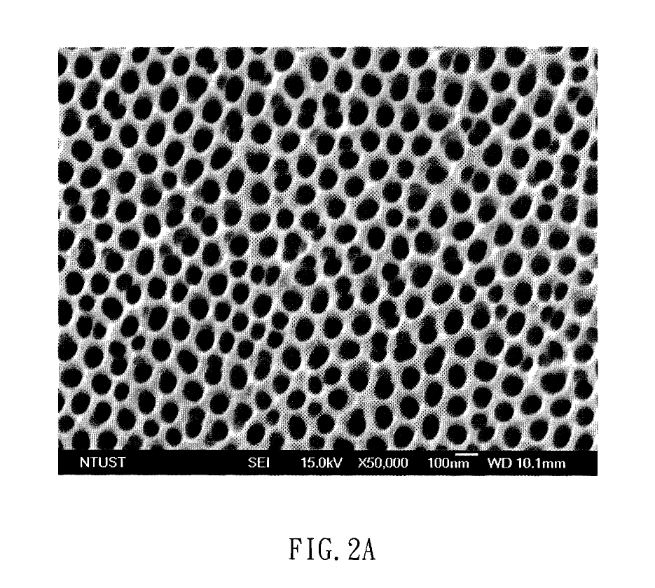

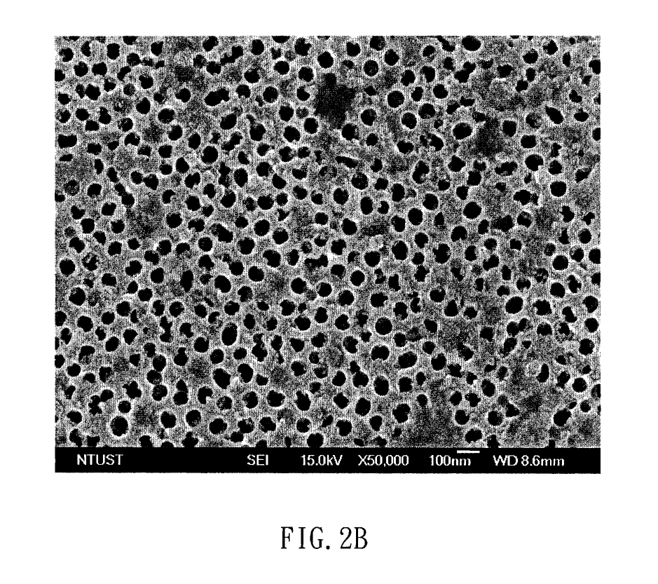

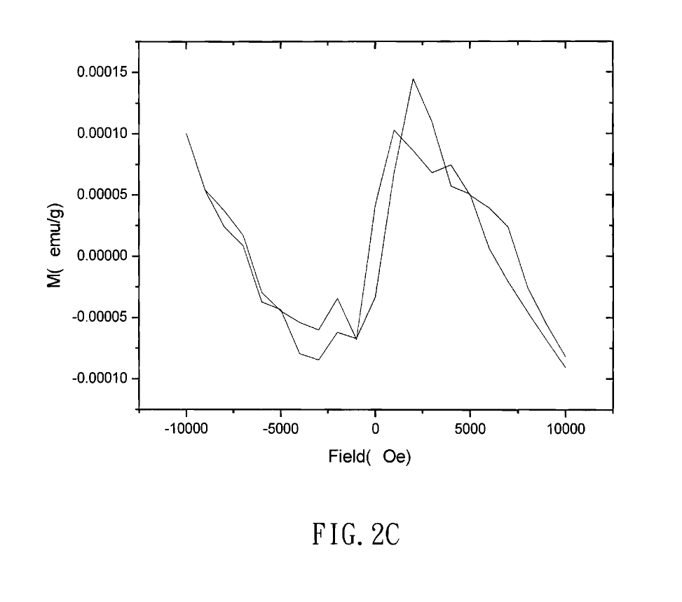

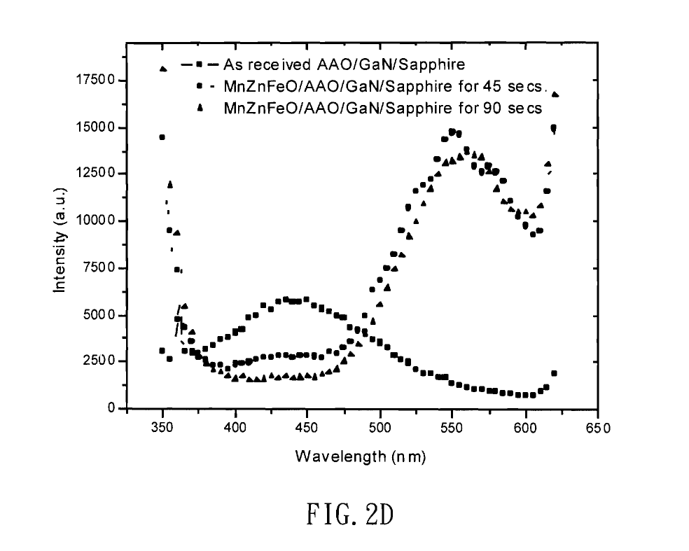

Preferably, according to the present invention, the mentioned super-paramagnetic layer may be manufactured without the use of lithography process. It should be noted that the following exemplary descriptions are illustrative only for specific implementation of the present invention and are not a complete embodiment of the semiconductor light-emitting device. First, a GaN layer is deposited over a sapphire substrate. After that, an aluminum layer is deposited over the GaN layer by the electron sputtering process, and then the aluminum layer is subjected to an anodic oxidation process, so as to form a nanoporous anodic alumina oxide (AAO) layer. FIG. 2A is an SEM (Scanning Electron Microscope) photo showing the surface structure of the AAO layer of this embodiment. It should be noted that the AAO layer herein functions as a template and is not needed to be removed. Then a MnZnFeO ferrite (MnZnFe ferrite) layer is formed over the AAO layer by means of in-situ spinning-precipitated technique. The preparation of MnZnFe ferrite includes mixing and stirring the MnCl₂, ZnCl₂, Fe₂O₃ of 0.5M, with a ratio of 0.5:0.5:1, and followed by the co-precipitation of 2M NaOH solution. With the use of in-situ spinning-precipitated technique along with the inter-titration process, MnZnFe ferrite is obtained. The surface structure of the MnZnFeO ferrite layer of this embodiment is shown in FIG. 2B, i.e. the SEM photo thereof. As shown in FIG. 2B, there are a plurality of nano-scale holes formed in the MnZnFeO ferrite layer. The magnetic characteristic of the MnZnFeO ferrite layer is measured with a superconducting quantum interference device (SQUID), and the measurement result thereof is shown in FIG. 2C. From FIG. 2C, it is clear that the MnZnFeO ferrite layer has an increased magnetic susceptibility, and an extremely low magnetic remanence and coercivity, which shows the super-paramagnetic characteristic of the MnZnFeO ferrite layer.

Three different samples are prepared according to the respective process as mentioned above for testing, including an AAO/GaN/Sapphire multi-layer structure, a 45MnZnFe ferrite/AAO/GaN/Sapphire multi-layer structure (the precipitation period of the ferrite is 45 seconds) and a 90 MnZnFe ferrite/AAO/GaN/Sapphire multi-layer structure (the precipitation period of the ferrite is 90 seconds). These three samples are excited with the use of a 325 He—Cd laser as an excitation light source, having the energy of 3.13 eV. The excited fluorescents are collected by lens assemblies and focused into a spectrometer. After being divided with the gratings of the spectrometer, the excited fluorescents are detected by a photomultiplier tube (PMT). The spectrum obtained is shown in FIG. 2D. As shown in FIG. 2D, it is clear from the fluorescent spectrum that with the increasing of the centrifugal precipitation period of the MnZnFe ferrite, the intensity of blue peak value is decreased, along with the generation of a secondary peak of wavelength at about 550 nm. The decrease in blue peak value of the fluorescent of the AAO/GaN/Sapphire multi-layer structure occurs due to the super-paramagnetic characteristic of the AAO layer, which is shown in the SQUID data. As to the red shift (i.e. the present of secondary peak) as shown in FIG. 2D, it is mainly caused by the modulation of the originally-emitted light, which is achieved by the super-paramagnetic characteristic of the MnZnFeO ferrite layer. The optical properties of the modulated light or the light to be modulated, for example, the wavelength of the peak value, the bandwidth, and the like, are adjustable by controlling the geometric parameters, such as the aperture (outer diameter), the arrangement and the like, of those nanostructures, e.g. the nano-scale holes or protrusions, formed in the MnZnFeO ferrite layer.

Referring back to FIG. 1, the first semiconductor cladding layer 16 is formed over the super-paramagnetic layer 14. One of the electrodes 18 is formed on the first semiconductor cladding layer 16, while the other electrode 18 is formed on the second semiconductor cladding layer 122. The electrodes 18 are used for current injection.

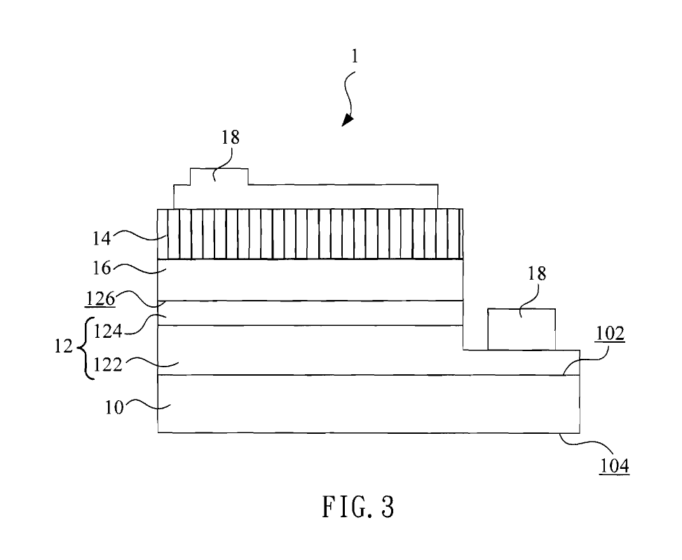

Please refer to FIG. 3, which shows the schematic cross-sectional view of a semiconductor light-emitting device 1 in accordance with another preferred embodiment of the present invention. The reference numbers shown in FIG. 3 are the same as those in FIG. 1, indicating the material layers as mentioned above, which are not illustrated in detail. The difference between the two embodiments is that for the embodiment as shown in FIG. 3, the first semiconductor cladding layer 16 is formed over the top surface 126 of the multi-layer structure 12, while the super-paramagnetic layer 14 is formed over the first semiconductor cladding layer 16. Besides, one of the electrodes 18 is formed on the super-paramagnetic layer 14.

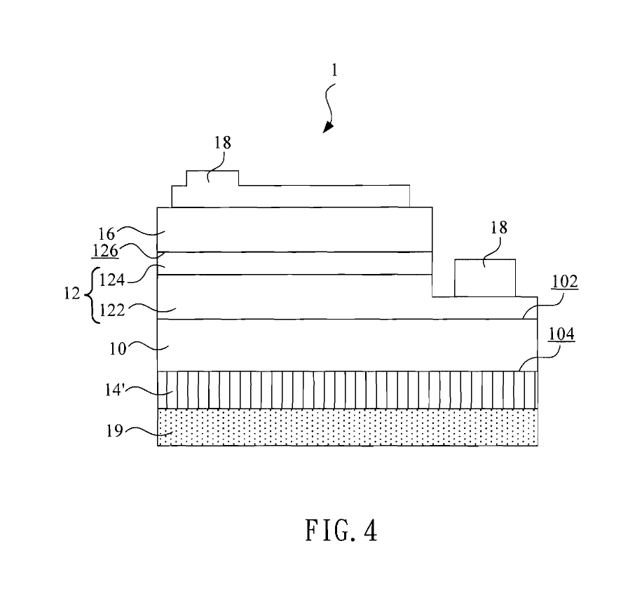

Now refer to FIG. 4, which shows a schematic cross-sectional view of a semiconductor light-emitting device 1 in accordance with a further preferred embodiment of the present invention. The reference numbers shown in FIG. 4 are almost the same as those in FIG. 1 and FIG. 3, indicating the material layers as mentioned above, which are not illustrated in detail. The embodiment as shown in FIG. 4 is different in that the semiconductor light-emitting device 1 includes a super-paramagnetic layer 14′ formed over the lower surface 104 of the substrate 10, and the semiconductor light-emitting device 1 further includes a reflective layer 19 formed over the super-paramagnetic layer 14′. The structure of the super-paramagnetic layer 14′ is designed for modulating the first light into the second light, while the reflective layer 19 is used for reflecting the light which is modulated by the super-paramagnetic layer 14′. In particular, with the semiconductor light-emitting device 1 as shown in FIG. 4, the light which is modulated by the super-paramagnetic layer 14′ may be mixed with the originally-emitted light.

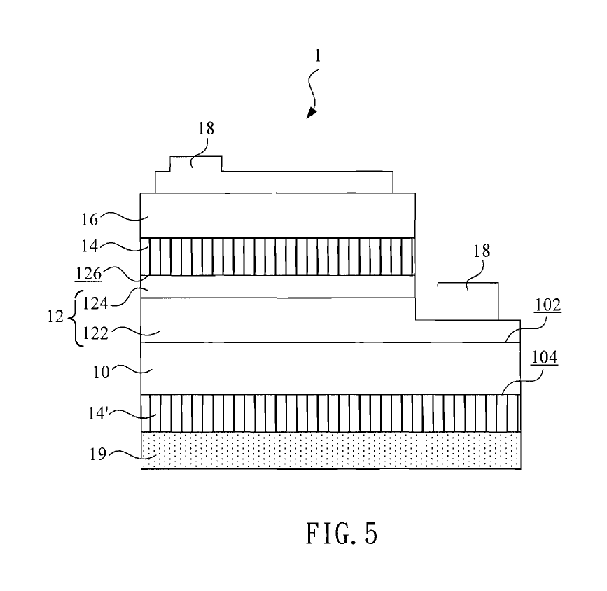

Refer to FIG. 5, which shows a schematic cross-sectional view of a semiconductor light-emitting device 1 in accordance with still another preferred embodiment of the present invention. The reference numbers shown in FIG. 5 are almost the same as those in FIG. 1, FIG. 3 and FIG. 4, indicating the material layers as mentioned above, which are not illustrated in detail. The embodiment as shown in FIG. 5 is different in that the semiconductor light-emitting device 1 includes two super-paramagnetic layer 14 and 14′. The structure of the super-paramagnetic layer 14′ is designed for modulating the first originally-emitted light into the second light, or into the lights other than the second light. The reflective layer 19 is used for reflecting the light which is modulated by the super-paramagnetic layer 14′.

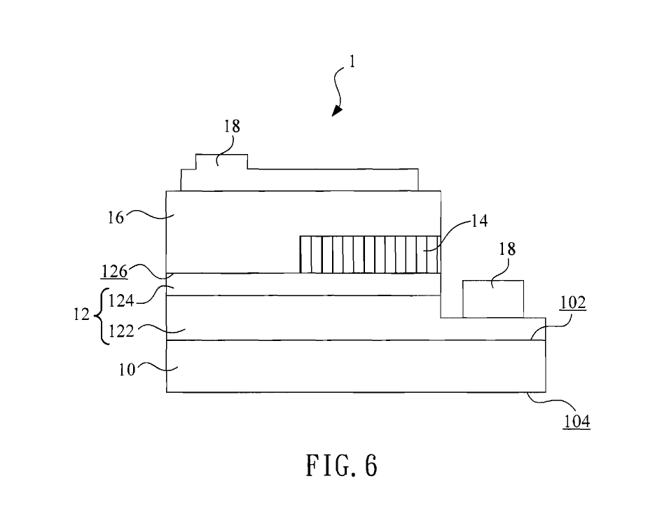

The cladding area of the super-paramagnetic layer 14 is determined depending on the final effect of the light emitted by the semiconductor light-emitting device 1. FIG. 6 is a schematic cross-sectional view of a semiconductor light-emitting device 1 in accordance with still another preferred embodiment of the present invention. The reference numbers shown in FIG. 6 are almost the same as those in FIG. 1, FIG. 3, FIG. 4 and FIG. 5, indicating the material layers as mentioned above, which are not illustrated in detail. According to the embodiment as shown in FIG. 6, the super-paramagnetic layer 14 is formed partially over the lower surface 126 of the multi-layer structure 12. In this case, a portion of the first light, which is not modulated into the second light, will be mixed with the second light to form a third light. Similarly, the cladding area of the super-paramagnetic layer 14 and 14′ as shown in FIGS. 3-5 may be adjusted corresponding to the finally-emitted light of the semiconductor light-emitting device 1, to form partially, but not entirely, over the multi-layer structure.

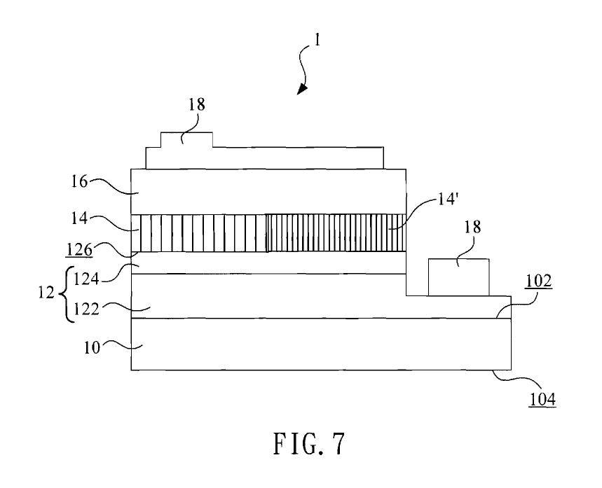

According to the demand on light mixing, the structure of semiconductor light-emitting device of the present invention is designed as shown in FIG. 7. Two super-paramagnetic layers 14 and 14′ are formed over the light-emitting layer 124, and alternatively, formed over the first semiconductor cladding layer 16. The red shift in respective originally-emitted lights caused by the two super-paramagnetic layers 14 and 14′ are different such that a desired mixing effect could be achieved. The respective cladding areas of the two super-paramagnetic layers 14 and 14′ are designed depending on the desired mixing effect. For example, in case that the light emitted from the light-emitting layer 124 is a UV light, the structure of the super-paramagnetic layer 14′ may be designed to modulate the UV light into the blue light, while the structure of the super-paramagnetic layer 14′ may be designed to modulate the UV light into the yellow light. In such a case, the two super-paramagnetic layers 14 and 14′ may be formed entirely over the light-emitting layer 124, so as to mix the modulated blue light with the modulated yellow light to get the white light.

Similarly, it is applicable to form three or even more than three super-paramagnetic layers with different light-modulating functions over the same material layer, e.g. the light-emitting layer 124, the first semiconductor cladding layer 16 or the lower surface 104 of substrate 10, of the semiconductor light-emitting device 1 in accordance with the present invention. Besides, in order to obtain two or even more than two different modulated lights, i.e. the secondary lights, the originally-emitted light may be modulated into two different lights upon passing through the holes or protrusions of two different sizes, which are formed in the same super-paramagnetic layer.

In addition, and more particularly, the super-paramagnetic characteristic of the super-paramagnetic layer of the semiconductor light-emitting device of the present invention may be suppressed by applying a carrier wave, so as to adjust the red shift in the originally-emitted light caused by the super-paramagnetic layer, wherein the extent of red shift in the originally-emitted light, which is caused by the super-paramagnetic layer, depends on the frequency of the applied carrier wave, and thereby the color of the finally-emitted light of the semiconductor light-emitting device of the present invention is adjustable. That is to say, with the application of the carrier wave, it is possible to form the display unit of an LED display by the use of two or even one single semiconductor light-emitting device of the invention. More particularly, even though two semiconductor light-emitting devices in accordance with the present invention are used as the display unit of an LED display, the constructions of both semiconductor light-emitting devices may be identical, for example, both for emitting the blue light or the UV light, such that the drive and control circuit of the display unit may be simplified. Other than the conventional schemes in which three different LEDs, i.e. the red, green and blue ones, are needed, it is apparent that the number of the components is reduced and the drive and control circuit is simplified with the use of display unit composed of the semiconductor light-emitting device in accordance with the present invention.

There are two methods of applying the carrier wave to the super-paramagnetic layer in accordance with the present invention, one of which is to add the carrier signal to the injected current signal from the two electrodes 18 directly, and the other is to form two respective electrodes other than the electrodes 18 on the super-paramagnetic layer for applying the required carrier signal to the super-paramagnetic layer. In this case, the two electrodes for applying the required carrier signal and the super-paramagnetic layer may be insulated from the multi-layer structure 12.

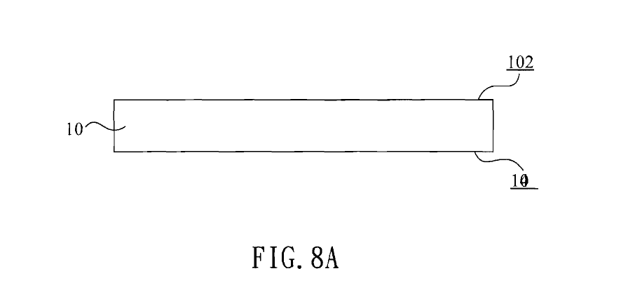

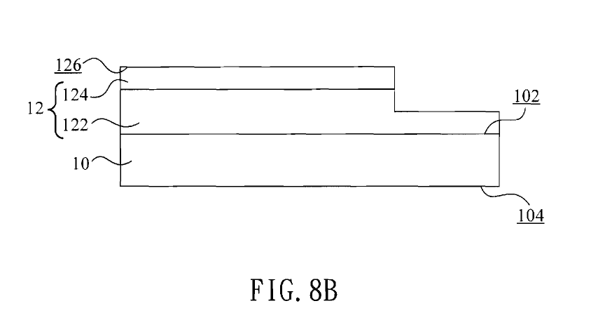

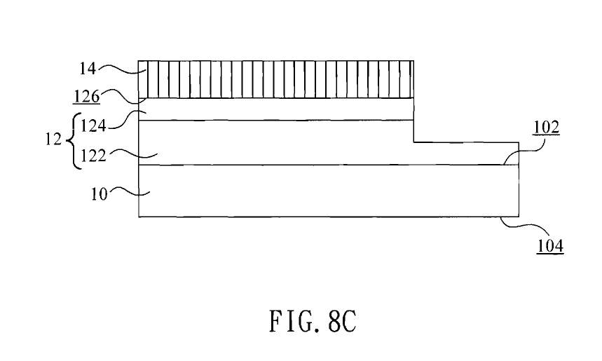

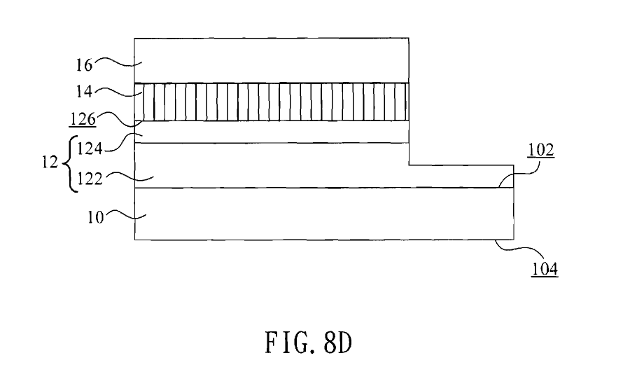

Please refer to FIG. 8A to FIG. 8D, which are schematic cross-sectional views illustrating the various steps of the fabrication process for manufacturing a semiconductor light-emitting device with light-modulating function in accordance with one preferred embodiment of the present invention. The fabrication process will be illustrated in more details.

First, a substrate 10 is prepared, as shown in FIG. 8A. The substrate 10 has an upper surface 102 and a lower surface 104 opposite to the upper surface 102.

After that, a multi-layer structure 12 composed of multiple epitaxial layers formed in sequence is formed over the upper surface 102 of substrate 10, as shown in FIG. 8B. The multi-layer structure 12 has a light-emitting layer 124, such as a pn-junction, a double hetero-junction or a multiple quantum well. The multi-layer structure 12 further includes a semiconductor cladding layer 122 which is formed prior to the formation of light-emitting layer 124. The multi-layer structure 12 has a top surface 126.

Then, a super-paramagnetic layer 14 is formed over the top surface 126 of the multi-layer structure 12, as shown in FIG. 8C. If there is a further semiconductor cladding layer formed as the most-top layer of the multi-layer structure, and thus provides the top surface 126, the semiconductor light-emitting device of the invention is accomplished after the formation of electrodes for current injection on the stacked structure shown in FIG. 8C. Alternatively, if the light-emitting layer 124 is formed as the most-top layer and thus provides the top surface 126, as shown in FIG. 8D, it needs to form a further semiconductor cladding layer 16 over the super-paramagnetic layer 14 prior to the formation of electrodes which are used for injecting currents, and the semiconductor light-emitting device is thus accomplished.

The functions, materials, processes, geometric parameters, and structural variations of the respective layer formed in the mentioned steps of the method according to the invention are similar to those as illustrated in the mentioned preferred embodiments, which are not repeated herein.

Comparing to the prior art, the present invention adopts the super-paramagnetic layer to modulate the originally-emitted light into a secondary light without the use of phosphors, so as to eliminate the drawbacks of low luminous efficiency and complex fabrication process of the conventional scheme, i.e. converting the originally-emitted light into the secondary light. Moreover, other than the conventional schemes in which three different LEDs, i.e. the red, green and blue ones, are needed, it is apparent that with the use of the semiconductor light-emitting device in accordance with the present invention, the display unit composed thereof is advantageous in the reduced number of the components and the simplified drive and control circuit.

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents that may be included within the spirit and scope of the invention as defined by the appended claims. Furthermore, in the following disclosure numerous specific details are given to provide a thorough understanding of the invention. However, it will be apparent to one skilled in the art that the present invention may be practiced without these specific details. In other instances, well-known methods, procedures, components, and circuits have not been described in detail, to avoid unnecessarily obscuring aspects of the present invention.

What is claimed is:

1. A semiconductor light-emitting device, comprising:
a substrate having a upper surface and a lower surface;
a multi-layer structure formed over the upper surface of the substrate, the multi-layer structure comprising a light-emitting layer to emit a first light and having a top surface; and
a first super-paramagnetic layer formed over the top surface of the multi-layer structure and/or the lower surface of the substrate, wherein a portion or most of the first light is modulated by the first super-paramagnetic layer into a second light upon passing through the first super-paramagnetic layer.

2. The semiconductor light-emitting device of claim 1, wherein the first super-paramagnetic layer is formed by a paramagnetic material.

3. The semiconductor light-emitting device of claim 2, wherein the first super-paramagnetic layer has a pattern formed by a plurality of nano-scale holes or a plurality of nano-scale protrusions.

4. The semiconductor light-emitting device of claim 3, wherein a portion of the nano-scale holes or the nano-scale protrusions of the first super-paramagnetic layer are dimensioned to modulate the first light passing therethrough into a third light.

5. The semiconductor light-emitting device of claim 3, wherein the first super-paramagnetic layer is formed substantially over the lower surface of the substrate, the semiconductor light-emitting device further comprising a reflective layer formed over the first super-paramagnetic layer which is formed over the lower surface of the substrate, wherein the reflective layer is configured for reflecting the second light, and a portion of the first light, which is not modulated into the second light, mixes with the second light to form a third light.

6. The semiconductor light-emitting device of claim 5, wherein the first super-paramagnetic layer is formed partially over the lower surface of the substrate, the semiconductor light-emitting device further comprising a second super-paramagnetic layer, wherein the second super-paramagnetic layer is formed over a portion of the lower surface of the substrate where the first super-paramagnetic layer is not formed, wherein the first light is modulated by the second super-paramagnetic layer into a third light upon passing through the second super-paramagnetic layer, the semiconductor light-emitting device further comprising a reflective layer, wherein the reflective layer is formed over the first super-paramagnetic layer and the second super-paramagnetic layer which is formed over the lower surface of the substrate, and is configured for reflecting the second light and the third light, wherein the first light mixes with the reflected second light and the reflected third light to form a forth light.

7. The semiconductor light-emitting device of claim 3, wherein the first super-paramagnetic layer is formed substantially over the top surface of the multi-layer structure.

8. The semiconductor light-emitting device of claim 3, wherein the first super-paramagnetic layer is partially formed over the top surface of the multi-layer structure, so as to enable a portion of the first light, which is not modulated into the second light, to mix with the second light to form a third light.

9. The semiconductor light-emitting device of claim 3, wherein the first super-paramagnetic layer is formed partially over the top surface of the multi-layer structure, the semiconductor light-emitting device further comprising a second super-paramagnetic layer formed over a portion of the top surface of the multi-layer structure where the first super-paramagnetic layer is not formed, wherein the first light is modulated by the second super-paramagnetic layer into a third light upon passing through the second super-paramagnetic layer.

10. The semiconductor light-emitting device of claim 3, wherein the first super-paramagnetic layer is formed partially over the top surface of the multi-layer structure, the semiconductor light-emitting device further comprising a second super-paramagnetic layer and a third super-paramagnetic layer formed over a portion of the top surface of the multi-layer structure where the first super-paramagnetic layer is not formed, wherein the first light is modulated by the second super-paramagnetic layer into a third light upon passing through the second super-paramagnetic layer, and is modulated by the third super-paramagnetic layer into a forth light when the first light passes through the third super-paramagnetic layer.

11. The semiconductor light-emitting device of claim 3, wherein the light-emitting layer is formed as a most-top layer of the multi-layer structure and the first super-paramagnetic layer is formed over the top surface of the multi-layer structure, the semiconductor light-emitting device further comprising a semiconductor cladding layer formed over the first super-paramagnetic layer.

12. The semiconductor light-emitting device of claim 3, wherein the first super-paramagnetic layer is formed over the top surface of the multi-layer structure, the multi-layer structure further comprising a semiconductor cladding layer formed as a most-top layer of the multi-layer structure.

13. The semiconductor light-emitting device of claim 3, further comprising two electrodes formed on the first super-paramagnetic layer.

14. The semiconductor light-emitting device of claim 13, wherein the electrodes and the first super-paramagnetic layer are insulated from the multi-layer structure.

15. The semiconductor light-emitting device of claim 3, wherein the light-emitting layer is formed by a III-V compound or a II-VI compound.

16. The semiconductor light-emitting device of claim 3, wherein the substrate is selected from a group consisting of SiO₂, Si, Ge, GaN, GaAs, GaP, AlN, sapphire, spinnel, Al₂O₃, SiC, ZnO, MgO, LiAlO₂, LiGaO₂ and MgAl₂O₄.

17. A method of fabricating a semiconductor light-emitting device, comprising the steps of:
providing a substrate having a upper surface and a lower surface;
forming a multi-layer structure on the upper surface of the substrate, wherein the multi-layer structure comprises a light-emitting layer for emitting a first light and has a top surface; and
forming a first super-paramagnetic layer over the top surface of the multi-layer structure and/or the lower surface of the substrate, wherein a portion or most of the first light is modulated by the first super-paramagnetic layer into a second light upon passing through the first super-paramagnetic layer.

18. The method of claim 17, wherein the first super-paramagnetic layer is formed by a paramagnetic material.

19. The method of claim 18, wherein the first super-paramagnetic layer has a pattern formed by a plurality of nano-scale holes or a plurality of nano-scale protrusions.

20. The method of claim 19, wherein a portion of the holes or the protrusions of the first super-paramagnetic layer are dimensioned to modulate the first light passing therethrough into a third light.

21. The method of claim 19, wherein the first super-paramagnetic layer is formed substantially over the lower surface of the substrate, the method further comprising the step of:
forming a reflective layer over the first super-paramagnetic layer which is formed over the lower surface of the substrate, wherein the reflective layer is configured for reflecting the second light, and wherein a portion of the first light, which is not modulated into the second light, mixes with the second light to form a third light.

22. The method of claim 21, wherein the first super-paramagnetic layer is formed partially over the lower surface of the substrate, the method further comprising the steps of:
forming a second super-paramagnetic layer over a portion of the lower surface of the substrate where the first super-paramagnetic layer is not formed, wherein the first light is modulated by the second super-paramagnetic layer into a third light upon passing through the second super-paramagnetic layer; and
forming a reflective layer over the first super-paramagnetic layer and the second super-paramagnetic layer which is formed over the lower surface of the substrate, wherein the reflective layer is configured for reflecting the second light and the third light, and wherein the first light mixes with the reflected second light and the reflected third light to form a forth light.

23. The method of claim 19, wherein the first super-paramagnetic layer is formed substantially over the top surface of the multi-layer structure.

24. The method of claim 19, wherein the first super-paramagnetic layer is formed partially over the top surface of the multi-layer structure, so as to enable a portion of the first light, which is not modulated into the second light, to mix with the second light to form a third light.

25. The method of claim 19, wherein the first super-paramagnetic layer is formed partially over the top surface of the multi-layer structure, the method further comprising the step of:
forming a second super-paramagnetic layer over a portion of the top surface of the multi-layer structure where the first super-paramagnetic layer is not formed, wherein the first light is modulated by the second super-paramagnetic layer into a third light upon passing through the second super-paramagnetic layer.

26. The method of claim 19, wherein the first super-paramagnetic layer is formed partially over the top surface of the multi-layer structure, the method further comprising the step of:
forming a second super-paramagnetic layer and a third super-paramagnetic layer over a portion of the top surface of the multi-layer structure where the first super-paramagnetic layer is not formed, wherein the first light is modulated by the second super-paramagnetic layer into a third light upon passing through the second super-paramagnetic layer, and is modulated by the third super-paramagnetic layer into a forth light upon passing through the third super-paramagnetic layer.

27. The method of claim 19, wherein the light-emitting layer is formed as a most-top layer of the multi-layer structure and the first super-paramagnetic layer is formed over the top surface of the multi-layer structure, the method further comprising the step of:
forming a semiconductor cladding layer over the first super-paramagnetic layer.

28. The method of claim 19, wherein the first super-paramagnetic layer is formed over the top surface of the multi-layer structure, the semiconductor light-emitting device further comprising a semiconductor cladding layer formed as a most-top layer of the multi-layer structure.

29. The method of claim 19, further comprises the step of:
forming two electrodes on the first super-paramagnetic layer.

30. The method of claim 29, wherein the electrodes and the first super-paramagnetic layer are insulated from the multi-layer structure.

31. The method of claim 19, wherein the light-emitting layer is formed by a III-V compound or a II-VI compound.

32. The method of claim 19, wherein the substrate is selected from a group consisting of SiO₂, Si, Ge, GaN, GaAs, GaP, AlN, sapphire, spinnel, Al₂O₃, SiC, ZnO, MgO, LiAlO₂, LiGaO₂ and MgAl₂O₄.
